(19) United States
(12) Patent Application Publication
(10) Pub. No.: US 2013/0129913 A1
(43) Pub. Date: May 23, 2013

(54) COATING APPARATUS AND COATING METHOD

(71) Applicant: Maochang Yan, Shenzhen (CN)

(72) Inventor: Maochang Yan, Shenzhen (CN)

(73) Assignee: SHENZHEN CHINA STAR OPTOELLECTRONICS TECHNOLOHY CO., LTD., Shenzhen (CN)

(21) Appl. No.: 13/379,671

(22) PCT Filed: Dec. 5, 2011
(86) PCT No.: PCT/CN11/83436

§ 371 Date: Dec. 21, 2011

(30) Foreign Application Priority Data
Nov. 21, 2011 (CN) 201110371649.0

(51) Int. Cl. C23C 16/52

(52) U.S. Cl. 427/8; 118/712

(57) ABSTRACT

The present invention relates to a coating apparatus having a coating platform, a coating extrusion head and a control unit controlling the coating extrusion head to perform a coating operation. The control unit is connected to the coating extrusion head. The coating apparatus further has an image sensor used to check the coating effect of a substrate placed on the coating platform. The present invention further relates to a coating method. The coating apparatus and the coating method use the image sensor to timely check coating defects.

### FIELD OF THE INVENTION

The present invention relates to a field of manufacturing liquid crystal panels, and more particularly to a coating apparatus having an image sensing device to timely detect coating defects and a coating method.

### BACKGROUND OF THE INVENTION

When manufacturing a liquid crystal panel, many kinds of coating technologies are widely used, which including inkjet coating technology, especially in the coating process of each film (for example, alignment film) of a liquid crystal display device, the inkjet coating technology is often used to perform a liquid material (coating material) coating (scheme view of normal statuses of before and after coating are shown in the top-left and top-right of FIG. 1). But when using the inkjet coating technology, a liquid-material extruding hole is often unable to extrude liquid materials due to an obstruction or bubbles (as shown in the bottom-left of FIG. 1), and thereby causes some positions on the substrate being coated to have no liquid crystal materials coated thereon and lead to an uneven film, and even causes a hole without being covered by the liquid material (as shown in the bottom-right of FIG. 1), and causes the product to have defects. Conventional technical solutions to the aforementioned problems of failing to extrude liquid materials by the liquid-material extruding hole, generally, are performed by the two means as follows:

1. check before producing: check if the inkjet equipment has a problem that the extruding hole thereof is unable to extrude before producing the products;

2. the downstream equipment checks the coating effect during the production process, and timely perform a clean treatment to the inkjet equipment once a problem is found.

However the first adopted means is unable to accurately monitor the real-time status of the extruding hole and then unable to find the extrusion problem occurred during the production process, and may easily cause a large amount of defective products; the second means cannot timely find the problem and easily cause defective products. And when the defective products are made, the defective products from the inkjet equipment to the check equipment may have to be re-made, the yield rate is lowered and the production cost is increased. The foregoing means still does not thoroughly solve the problem that a few extruding failures may be caused by the extruding hole during a long-time production process, and thereby causes following problems that the inkjet equipment is temporarily unable to work and a large amount of defective products are manufactured.

Hence, it is necessary to provide a coating apparatus and a coating method to overcome the problems existing in the conventional technology.

### SUMMARY OF THE INVENTION

An object of the present invention is to provide a coating apparatus and a coating method that use an image sensor to timely check coating defects so as to solve a technical problem that conventional coating apparatuses and coating methods thereof easily produce defective products and have low producing efficiency.

In order to solve the abovementioned problem, the present invention provides a technical solution as follows:

The present invention relates to a coating apparatus comprising a coating platform, a coating extrusion head and a control unit controlling the coating extrusion head to performing an coating operation, wherein the control unit is connected to the coating extrusion head, and the coating apparatus further comprises a driving system, an image sensor used to check the coating effect of a substrate placed on the coating platform and a locating unit used to locate the position of coating defects, and the driving system is connected to the coating platform and the coating extrusion head, respectively.

In the coating apparatus mentioned in the present invention, the image sensor is connected to the locating unit.

In the coating apparatus mentioned in the present invention, the coating apparatus further comprises a repairing extrusion head used to repair a coating-defective area on the substrate.

In the coating apparatus mentioned in the present invention, the repairing extrusion head is integrated with the coating extrusion head.

The present invention further relates to a coating apparatus comprising a coating platform, a coating extrusion head and a control unit controlling the coating extrusion head to perform a coating operation, and the control unit is connected to the coating extrusion head, wherein the coating apparatus further comprises an image sensor used to check the coating effect of a substrate placed on the coating platform.

In the coating apparatus mentioned in the present invention, the coating apparatus further comprises a locating unit used to locate the position of coating defects, and the image sensor is connected to the locating unit.

In the coating apparatus mentioned in the present invention, the coating apparatus further comprises a repairing extrusion head used to repair a coating-defective area on the substrate.

In the coating apparatus mentioned in the present invention, the repairing extrusion head is integrated with the coating extrusion head.

In the coating apparatus mentioned in the present invention, the coating apparatus further comprises a driving system, and the driving system is connected to the coating platform, the driving system is connected to the coating extrusion head, or the driving system is connected to the coating platform and the coating extrusion head, respectively.

In the coating apparatus mentioned in the present invention, the coating apparatus further comprises an alarm device used to generate an alarm signal according to an occurrence of coating defects.

In the coating apparatus mentioned in the present invention, the coating apparatus uses an inkjet coating technology to perform an alignment-film coating operation on the substrate on the coating platform.

The present invention further relates to a coating method which comprises steps of: performing a liquid coating operation on a substrate on a coating platform; and using an image sensor to check the coating effect of the substrate.

In the coating method mentioned in the present invention, further include a step of locating the position of coating defect according to the check result.

In the coating method mentioned in the present invention, further include a step of performing repairing to the coating-defective area on the substrate according to the locating data.

In the coating method mentioned in the present invention, further include a step of orderly performing a spreading treatment and a drying treatment to the substrate after finishing repairing.

In the coating method mentioned in the present invention, the step of performing a liquid coating operation on a substrate on a coating platform is using an inkjet coating technology to perform an alignment-film coating operation on the substrate on the coating platform.

In the coating method mentioned in the present invention, the coating method further includes a step of: generating an alarm signal according to the check result for the occurrence of coating defects.

Implementing the coating apparatus and the coating method of the present invention has follow advantages: using the image sensor to timely check coating defects so as to solve a technical problem that conventional coating apparatuses and coating methods thereof easily produce defective products and have low producing efficiency.

In order to make the contents of the present invention to be easily understood, the preferred embodiments of the present invention are described in detail in cooperation with accompanying drawings as follows:

### DESCRIPTION OF THE DRAWINGS

FIG. 1 is a schematic view of the statuses before and after coating when a conventional inkjet coating technique is used to perform liquid material coating;

FIG. 2 is a schematic structural view of a first preferred embodiment of a coating apparatus in accordance with the present invention;

FIG. 3 is a schematic structural view of a second preferred embodiment of a coating apparatus in accordance with the present invention; and

FIG. 4 is a schematic flow chart of a preferred embodiment of a coating method in accordance with the present invention.

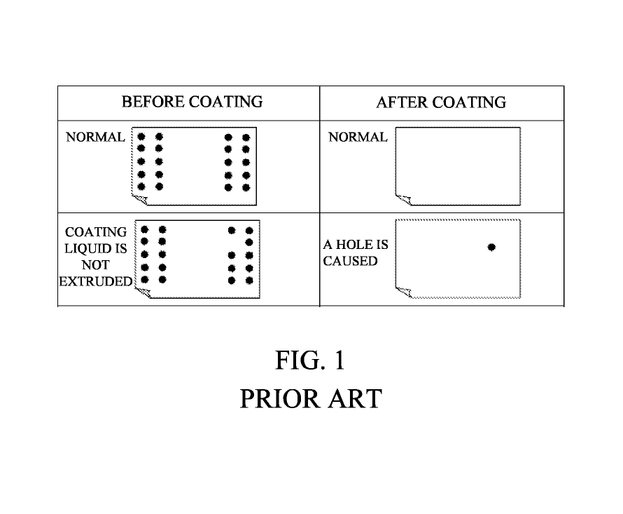

### DETAILED DESCRIPTION OF THE INVENTION

Following description of each embodiment is referring to the accompanying drawings so as to illustrate practicable specific embodiments in accordance with the present invention. In the drawings, units with similar structure are labeled with the same reference number.

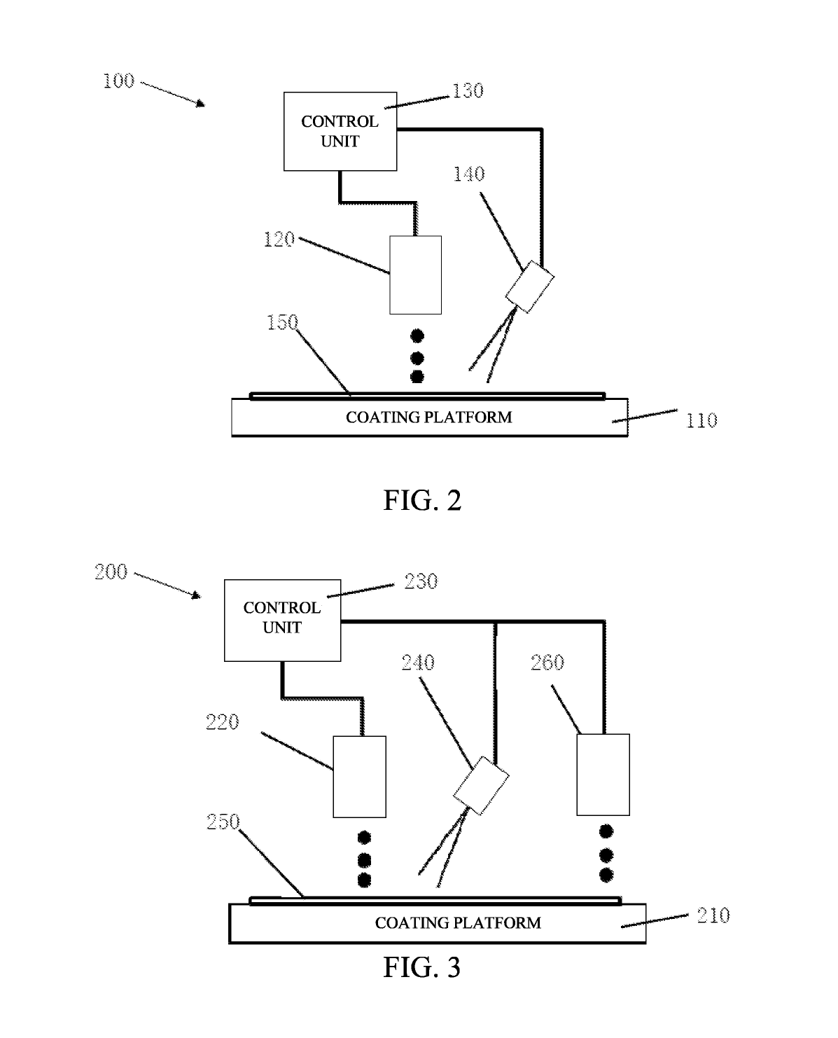

The present invention relates to a coating apparatus, FIG. 2 shows a schematic structural view of a first preferred embodiment of a coating apparatus in accordance with the present invention. A coating apparatus 100 in the figure comprises a coating platform 110, a coating extrusion head 120, a control unit 130 and an image sensor 140. The coating platform 110 is used to hold a substrate 150 waiting to be coated. The coating extrusion head 120 is used to extrude coating liquid. The control unit 130 is used to control the coating extrusion head 120 to perform a coating operation. The image sensor 140 is used to check the coating effect of the substrate 150 placed on the coating platform 110, wherein the control unit 130 is connected to the coating extrusion head 120 and the image sensor 140, respectively.

The coating apparatus 100 of the present invention has the image sensor 140 mounted therein so as to be able to timely find the coating defects of the substrate 150 that is under coating process. With reference to FIG. 2, when the coating apparatus 100 is working, the coating platform 110 and the coating extrusion head 120 move relatively to each other with a certain speed, to make the coating extrusion head 120 to extrude the coating liquid to corresponding positions on the substrate 150. The image sensor 140 synchronously scans the position of the coating liquid on the substrate 150 to compare with a standard sample data (the standard sample data can be stored in the image sensor or other storage devices), if the position of the coating liquid is the same with the standard sample data, then determine that the coating is normal; if the coating liquid is found to be different from the standard sample data, then determine that the coating liquid is not extruded or other coating-defective problems has occurred, the image sensor 140 then may make the control unit 130 to make the coating apparatus 100 to automatically stop the coating operation and wait for related personnel to solve the problem, or the image sensor 140 may make an alarm device (for example, sound alarm and/or light alarm) to generate an alarm to warn the operator that coating defect has occurred. Therefore the operator can timely solve the coating defect problem to reduce defective products.

FIG. 3 is a schematic structural view of a second preferred embodiment of a coating apparatus in accordance with the present invention, the coating apparatus 200 in the figure is based on the first preferred embodiment and further comprises a repairing extrusion head 260, and the repairing extrusion head 260 is used to repair the coating defects of the substrate 250. The coating apparatus 200 further comprises a locating unit, and the locating unit is used to locate the position of coating defects, and the locating unit is connected to the image sensor 240.

With reference to FIG. 3, when the coating apparatus 200 is working, the coating platform 210 and the coating extrusion head 220 moves relatively to each other with a certain speed, such that the coating extrusion head 220 extrude coating liquid to corresponding positions on the substrate 250. The image sensor 240 synchronously scans the position of the coating liquid on the substrate 250 to compare with a standard sample data, if the position of the coating liquid is the same with the standard sample data, then determine that the coating is normal; if the coating liquid is found to be different from the standard sample data, then determine that the coating liquid is not extruded or other coating-defective problems has occurred, then transmit a signal about the substrate position to which the un-extruded coating liquid corresponds to the locating unit. The locating unit then calculates the coordinates of the substrate position that needs to repair after receiving the signal about the corresponding substrate position, and then transmits the coordinates to a corresponding driving system. The driving system then controls the coating platform 210 and the repairing extrusion head 260 to move relatively to each other, so as to make the repairing extrusion head 260 to extrude coating liquid onto the substrate position to which the un-extruded coating liquid corresponds to perform a repair operation to the position. The locating unit herein can be mounted alone or mounted in the control unit 230.

The driving system of the coating apparatus of the present invention has many kinds of implementations, for example, the driving system may drive the coating platform 210 alone, or the driving system may drive the coating extrusion head 220 and the repairing extrusion head 260 alone, or the driving system may synchronously drive the coating platform 210, the coating extrusion head 220 and the repairing extrusion head 260.

When the driving system drives the coating platform 210 alone, the driving system and the coating platform 210 are connected, the positions of the coating extrusion head 220 and the repairing extrusion head 260 are fixed, when the substrate 250 needs to move relatively to coating extrusion head 220 or the repairing extrusion head 260 to perform coating or repairing, it only needs to drive the coating platform 210 to make corresponding movements, hence the driving method is relatively simple.

When the driving system drives the coating extrusion head 220 and the repairing extrusion head 260 alone, the driving system is connected to the coating extrusion head 220 and the repairing extrusion head 260, and the position of the coating platform 210 is fixed, when the substrate 250 needs to move relatively to the coating extrusion head 220 or the repairing extrusion head 260 to perform coating or repairing, it only needs to drive the coating extrusion head 220 or the repairing extrusion head 260 to make corresponding movements.

When the driving system synchronously drives the coating platform 210, the coating extrusion head 220 and the repairing extrusion head 260, the driving system is connected to the coating platform 210, the coating extrusion head 220 and the repairing extrusion head 260, and the coating platform 210 is in charge of the movement along a certain direction(for example, an X direction), and the coating extrusion head 220 and the repairing extrusion head 260 are in charge of the movement along another direction (for example, a Y direction perpendicular to the X direction). When the substrate 250 needs to move relatively to the coating extrusion head 220 or the repairing extrusion head 260 to perform coating or repairing, the coating platform 210 and the coating extrusion head 220 or the repairing extrusion head 260 are driven to move along corresponding directions, respectively, such driving method is much faster.

The repairing extrusion head of the coating apparatus can further be integrated with the coating extrusion head. Then the cost for the coating apparatus can be further reduced, and makes the repairing to be much faster. Once the image sensor finds out the problem that the coating liquid is not extruded, the coating liquid can be immediately coated to perform repairing.

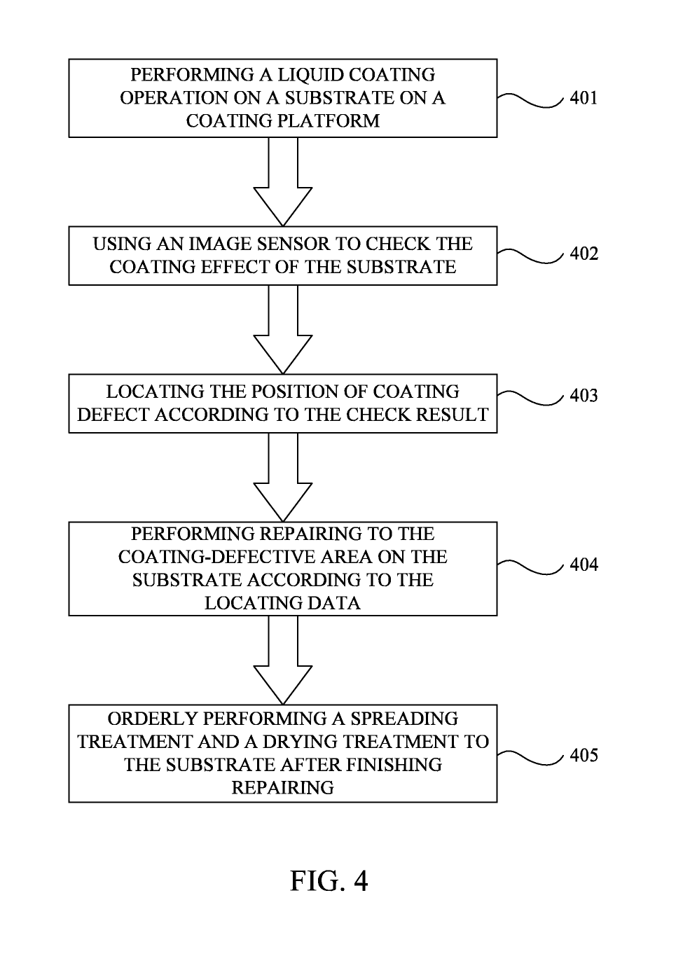

The present invention further relates to a coating method, as shown in FIG. 4, a schematic flow chart of a preferred embodiment of the coating method in accordance with the present invention, the coating method comprises steps:

Step 401: performing a liquid coating operation on a substrate on a coating platform;

Step 402: using an image sensor to check the coating effect of the substrate;

Step 403: locating the position of coating defect according to the check result;

Step 404: performing repairing to the coating-defective area on the substrate according to the locating data; and

Step 405: orderly performing a spreading treatment and a drying treatment to the substrate after finishing repairing.

The coating method with the check step by the image sensor can timely find out the coating defects on the substrate which is under coating process, and with a repairing step at the same time, it can automatically repair the coating defects on the substrate which is under coating process. When performing the coating method of the present invention, first perform a liquid coating operation on the substrate on the coating platform, and synchronously use the image sensor to check the coating effect of the substrate that is under coating process, if the check result is fine, then continue liquid coating until the coating process is finished; if the check result indicates a coating defect, then locate the position of the coating defect, and then perform repairing to the coating defect on the substrate according to the locating data until the coating process is finished. After coating, then perform a spreading treatment to the substrate to form an even liquid film on the surface of the substrate, and then perform a drying treatment to the liquid film to make it become a solid film.

The coating method of the present invention preferably uses an inkjet coating technology to perform an alignment-film coating operation on the substrate on the coating platform, such that an inkjet apparatus is used to directly perform repairing on the position of coating defect on the substrate, and thereby lower the defective rate of the substrate and reduce the remaking cost for the products, and meanwhile enhance the efficiency of the inkjet apparatus and increase the quality of alignment film.

In conclusion, although the present invention has been described with reference to embodiments thereof, these embodiments merely illustrate concrete examples, not restrict the present invention. And it is understood that many changes and modifications to the described embodiment can be carried out without departing from the scope and the spirit of the invention that is intended to be limited only by the appended claims.

What is claimed is:

1. A coating apparatus, comprising a coating platform, a coating extrusion head and a control unit controlling the coating extrusion head to performing an coating operation, and the control unit is connected to the coating extrusion head, characterized in that: the coating apparatus further comprises a driving system, an image sensor used to check the coating effect of a substrate placed on the coating platform and a locating unit used to locate the position of coating defects, and the driving system is connected to the coating platform and the coating extrusion head, respectively.

2. The coating apparatus as claimed in claim 1, characterized in that: the image sensor is connected to the locating unit.

3. The coating apparatus as claimed in claim 2, characterized in that: the coating apparatus further comprises a repairing extrusion head used to repair a coating-defective area on the substrate.

4. The coating apparatus as claimed in claim 3, characterized in that: the repairing extrusion head is integrated with the coating extrusion head.

5. A coating apparatus, comprising a coating platform, a coating extrusion head and a control unit controlling the coating extrusion head to perform a coating operation, and the control unit is connected to the coating extrusion head, characterized in that: the coating apparatus further comprises an image sensor used to check the coating effect of a substrate placed on the coating platform.

6. The coating apparatus as claimed in claim 5, characterized in that: the coating apparatus further comprises a locating unit used to locate the position of coating defects, and the image sensor is connected to the locating unit.

7. The coating apparatus as claimed in claim 6, characterized in that: the coating apparatus further comprises a repairing extrusion head used to repair a coating-defective area on the substrate.

8. The coating apparatus as claimed in claim 7, characterized in that: the repairing extrusion head is integrated with the coating extrusion head.

9. The coating apparatus as claimed in claim 5, characterized in that: the coating apparatus further comprises a driving system, and the driving system is connected to the coating platform, the driving system is connected to the coating extrusion head, or the driving system is connected to the coating platform and the coating extrusion head, respectively.

10. The coating apparatus as claimed in claim 6, characterized in that: the coating apparatus further comprises an alarm device used to generate an alarm signal according to an occurrence of coating defects.

11. The coating apparatus as claimed in claim 5, characterized in that: the coating apparatus uses an inkjet coating technology to perform an alignment-film coating operation on the substrate on the coating platform.

12. A coating method, characterized in that: the coating method comprises steps of: performing a liquid coating operation on a substrate on a coating platform; and using an image sensor to check the coating effect of the substrate.

13. The coating method as claimed in claim 12, characterized in that: the coating method further comprises a step of: locating the position of coating defect according to the check result.

14. The coating method as claimed in claim 13, characterized in that: the coating method further comprises a step of: performing repairing to the coating-defective area on the substrate according to the locating data.

15. The coating method as claimed in claim 14, characterized in that: the coating method further comprises a step of: orderly performing a spreading treatment and a drying treatment to the substrate after finishing repairing.

16. The coating method as claimed in claim 12, characterized in that: the step of performing a liquid coating operation on a substrate on a coating platform is using an inkjet coating technology to perform an alignment-film coating operation on the substrate on the coating platform.

17. The coating method as claimed in claim 12, characterized in that: the coating method further comprises a step of: generating an alarm signal according to the check result for the occurrence of coating defects.
